(19) United States
(12) Patent Application Publication
(10) Pub. No.: US 2013/0223026 A1
(43) Pub. Date: Aug. 29, 2013

(54) ELECTRONIC DEVICE WITH DISTRIBUTION BOARD

(71) Applicants: TENG-YUAN SHU, Tu-Cheng (TW); YU-CHI TSAI, Tu-Cheng (TW)

(72) Inventors: TENG-YUAN SHU, Tu-Cheng (TW); YU-CHI TSAI, Tu-Cheng (TW)

(73) Assignee: HON HAI PRECISION INDUSTRY CO., LTD., Tu-Cheng (TW)

(21) Appl. No.: 13/474,626

(22) Filed: May 17, 2012

(30) Foreign Application Priority Data
Feb. 29, 2012 (TW) 101106615

(51) Int. Cl. H05K 7/14

(52) U.S. Cl. 361/756

(57) ABSTRACT

An electronic device includes a housing, a main board, at least one guiding rail, and a distribution board. The main board is received in the housing, and a reception portion formed between the main board and the housing. The guiding rail is fixed in the reception portion and defines at least one guiding groove therein. The distribution board includes at least one sliding rail corresponding to the guiding groove. The sliding rail is slidably received in the guiding groove, and the distribution board is inserted into or pulled out of the reception portion when the sliding rail slides along the guiding groove.

### BACKGROUND

1. Technical Field

The present disclosure relates to electronic devices, and particularly to an electronic device with a distribution board.

2. Description of Related Art

Many electronic devices, such as personal computers (PCs) and servers, include distribution boards. External power supplies can be electrically connected to main boards of the electronic devices via the distribution boards. A distribution board of an electronic device can convert a voltage provided by an external power supply to various types of working voltages suitable for various components of the electronic device, and transmit the correct working voltages to the respective components.

A distribution board of an electronic device may be positioned under a main board of the electronic device to conserve space in the electronic device. However, when the distribution board needs to be checked or repaired, the main board positioned above the distribution board may have to be detached. The operation for detaching and reassembling the main board is tedious and time consuming.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is an assembled view of an electronic device, according to an exemplary embodiment.

FIG. 2 is a view of the electronic device shown in FIG. 1 in a first state of use.

FIG. 3 is a view of the electronic device shown in FIG. 1 in a second state of use.

FIG. 4 is a disassembled view of the electronic device shown in FIG. 1.

### DETAILED DESCRIPTION

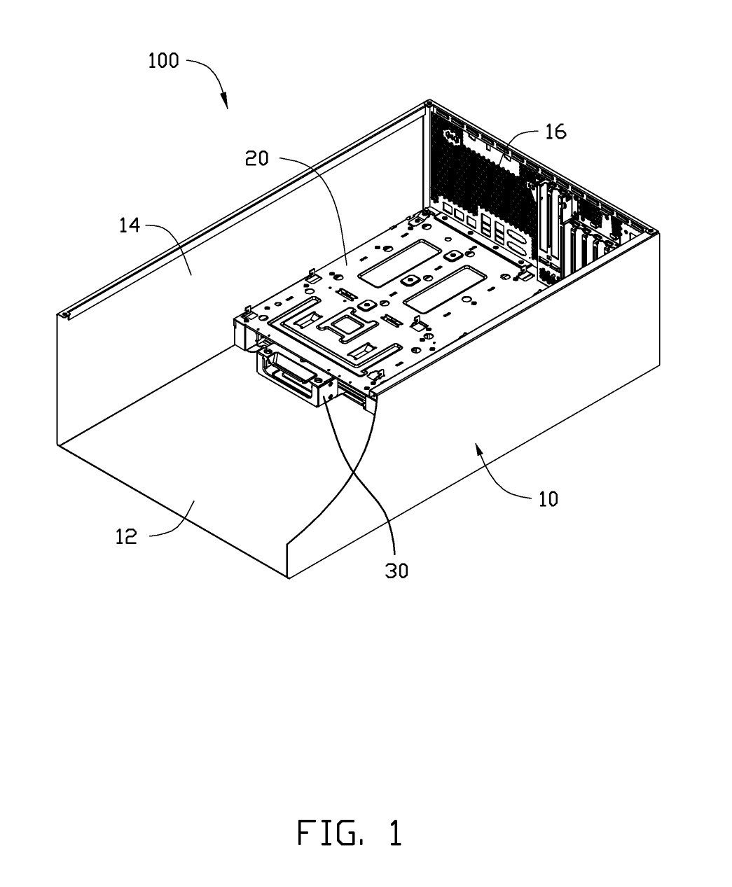

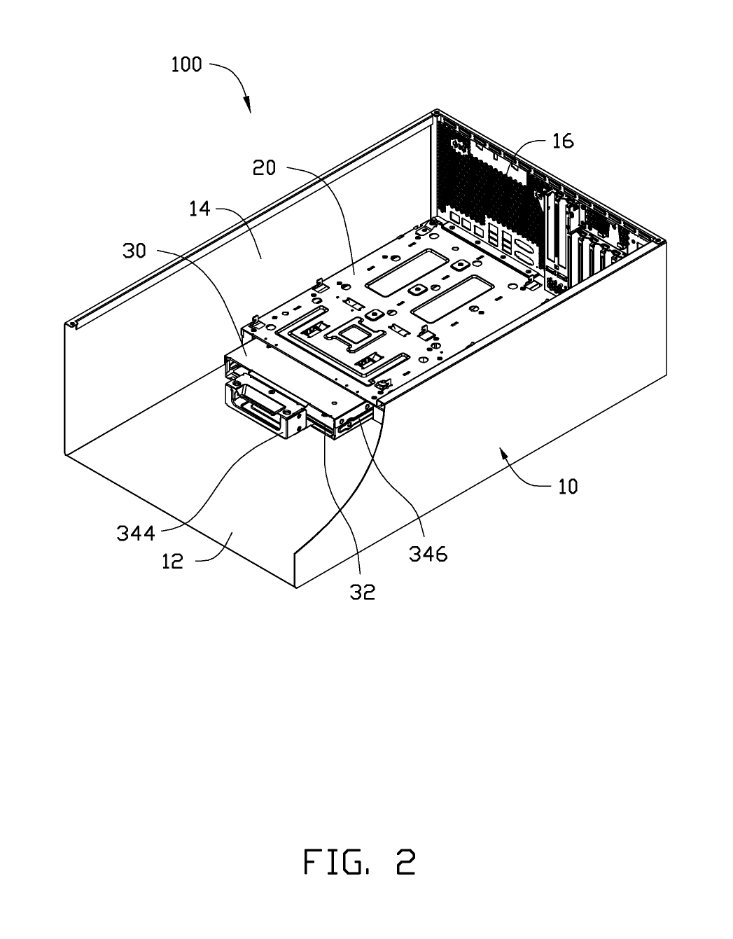

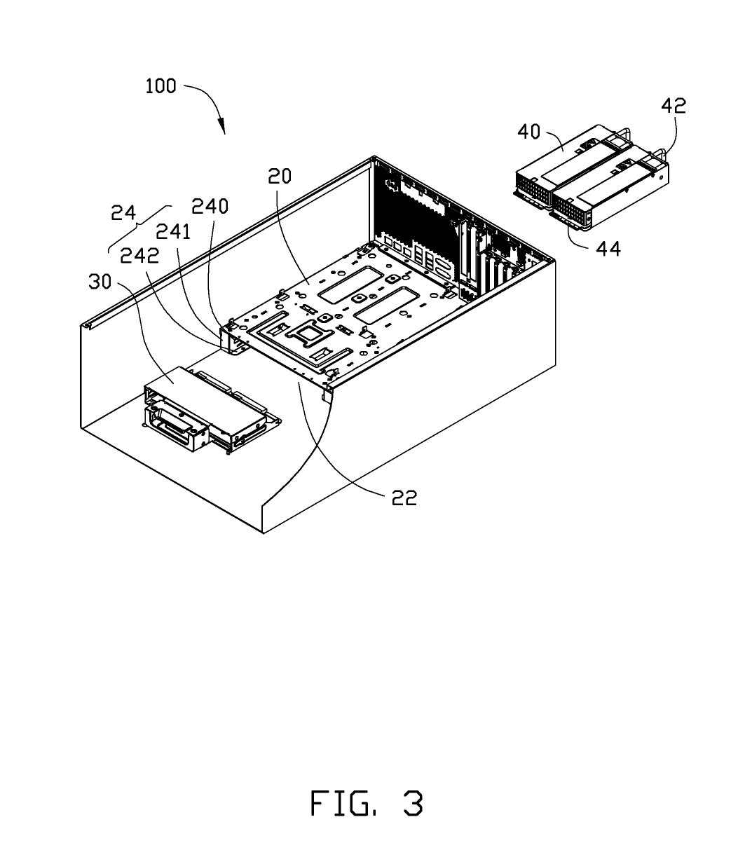

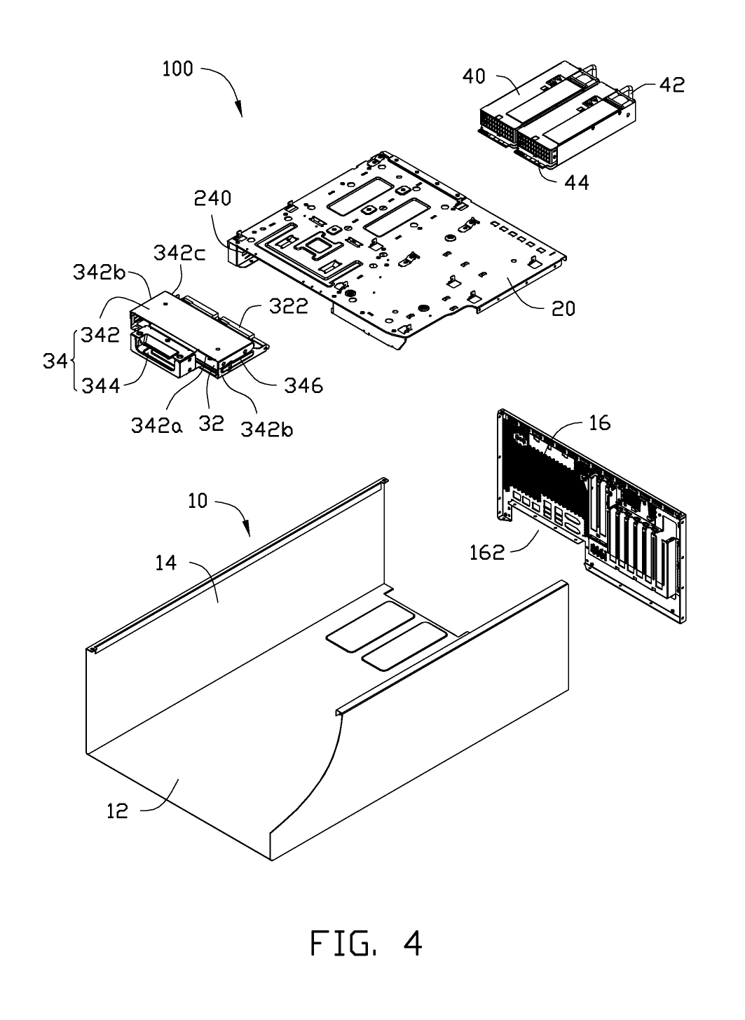

FIGS. 1-4 show an electronic device 100, according to an exemplary embodiment. The electronic device 100 includes a housing 10, a main board 20, a distribution board 30, and a power supply 40. The main board 20, the distribution board 30, and the power supply 40 are all received in the housing 10.

The housing 10 includes a base panel 12, two side panels 14, and a back panel 16. The base panel 12, the side panels 14, and the back panel 16 are all substantially planar panels. Both the side panels 14 and the back panel 16 are perpendicularly mounted on the base panel 12. The side panels 14 are parallel to each other, and two ends of the back panel 16 are respectively perpendicularly connected to the two side panels 14, such that, horizontally, the side panels 14 and the back panel 16 form a substantially U-shaped frame. The back panel 16 defines an aperture 162 adjacent to the base panel 12.

The main board 20 is substantially a rectangular panel, and a width of the main board 20 equals a distance between the two side panels 14. The main board 20 is received in the U-shaped frame formed by the side panels 14 and the back panel 16, and positioned substantially parallel to the base panel 12, so that a reception portion 22 is formed between the main board 20 and the base panel 12. Two opposite side edges of the main board 20 are respectively perpendicularly fixed on the two side panels 14, a third side edge of the main board 20 is perpendicularly fixed on the back panel 16, and a fourth side edge of the main board 20 is positioned towards an opening of the U-shaped frame formed by the side panels 14 and the back panel 16.

The electronic device 100 further includes at least one guiding rail 24. The guiding rail 24 includes a guiding portion 241 and a retaining portion 242. The guiding portion 241 is substantially a flanged bar, and the retaining portion 242 is substantially the flange extending inwards from a bottom corner of the guiding portion 241. Both the guiding portion 241 and the retaining portion 242 are received in the reception portion 22. The guiding portion 241 is positioned parallel to the two side panels 14 and has a function of securing the main board 20 a certain distance above the floor of the reception portion 22 (i.e., the base panel 12). Two opposite side surfaces of the guiding portion 241 are respectively fixed on the main board 20 and the base panel 12. A third side surface of the guiding portion 241 is fixed on one of the two side panels 14. A fourth side surface of the guiding portion 241, which is positioned towards the reception portion 22, defines a guiding groove 240. The guiding groove 240 is parallel to the main board 20 and the base panel 12. The underside of the retaining portion 242 is flatly fixed on the base panel 12.

The distribution board 30 includes a distribution circuit 32 and a case 34. The case 34 includes a main body 342 and an operation member 344. The main body 342 is substantially a cuboid box, and includes an operation side 342a, two sliding sidewalls 342b, and a connection side 342c. The operation side 342a is substantially parallel to the connection side 342c, and the two sliding sidewalls 342b are substantially parallel to each other and perpendicularly mounted between the operation side 342a and the connection side 342c. At least one sliding rail 346 corresponding to the guiding groove 240 is formed on one of the sliding sidewalls 342b. The distribution circuit 32 is received in the main body 342, and includes two interfaces 322 protruding from the connection side 342c. The operation member 344 can be a handle or other common structure facilitating pulling and pushing by hand, and is fixed on the operation side 342a.

The power supply 40 may be a battery holder or a household power supply adapter. The power supply 40 is substantially cuboid, and includes two handles 42 formed on one end thereof and two interfaces 44 formed on another opposite end thereof. The shape and size of the power supply correspond to those of the aperture 162, and thus the end of the power supply 40 with the interfaces 44 formed thereon can be inserted into the reception portion 22 and removed via the aperture 162. Positions of the interfaces 44 are configured to correspond to positions of the interfaces 322. When the power supply 40 is inserted into the reception portion 22, the interfaces 44 can engage with the interfaces 322, thereby electrically connecting the distribution circuit 32 with the power supply 40.

In assembly, the connection side 342c of the distribution board 30 is positioned towards the reception portion 22, and the distribution board 30 is inserted into the reception portion 22. The sliding rail 346 is slidably received in the guiding groove 240, such that the distribution board 30 slidably engages with the guiding portion 241 under the main board 20. The distribution board 30 is then pushed to slide along the guiding groove 240, until the main body 342 is entirely received in the reception portion 22 and the operation member 34 is exposed out of the reception portion 22. Thus, the distribution circuit 32 is electrically connected to the main board 20 by commonly used methods, such as wires.

The end of the power supply 40 with the interfaces 44 formed thereon is inserted into the reception portion 22 via the aperture 162, and the interfaces 44 respectively engage with the interfaces 322 to electrically connect the distribution circuit 32 with the power supply 40. In this way, the power supply 40 can supply electric power to the distribution circuit 32. The distribution circuit 32 distributes the voltage provided by the power supply 40 to various components of the electronic device 100.

When the distribution board 30 needs to be checked, repaired or changed, the distribution board 30 can be pulled out of and re-inserted into the reception portion 22 along the sliding groove 240. The operation member 344 facilitates operations for moving the distribution board 30. Furthermore, when the power supply 40 needs to be checked, repaired or changed, the power supply 40 can also be pulled out of and re-inserted into the reception portion 22 via the aperture 162. The handles 42 facilitate the handling of the power supply 40. Compared with electronic devices of related art which use distribution boards, the electronic device 100 does not require the detachment of the main board 20 when the distribution board 30 and the power supply 40 is checked, repaired or changed.

In other exemplary embodiments, the electronic device 100 can also include another guiding rail 24. The additional guiding rail 24 can be mounted between the main board 20 and the base panel 12, and a distance between the two guiding rails 24 can be determined according to a width of the case 34. Correspondingly, the case 34 can include two sliding rails 346, which are respectively formed on the two sliding sidewalls 342b, and are respectively slidably received in the guiding grooves 240 of the two guiding rails 24.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. An electronic device, comprising:
a housing;
a main board received in the housing, a reception portion formed between the main board and the housing;
at least one guiding rail fixed in the reception portion and defining at least one guiding groove therein; and
a distribution board including at least one sliding rail corresponding to the guiding groove;
wherein the sliding rail is slidably received in the guiding groove, and the distribution board is inserted into or pulled out of the reception portion when the sliding rail slides along the guiding groove.

2. The electronic device as claimed in claim 1, wherein the housing includes a base panel, two side panels, and a back panel, which are all substantially planar panels; both the side panels and the back panel perpendicularly mounted on the base panel, the side panels being parallel to each other, and two ends of the back panel respectively perpendicularly connected to the two side panels.

3. The electronic device as claimed in claim 2, wherein the main board is substantially a rectangular panel, and is positioned substantially parallel to the base panel to form the reception portion between the main board and the base panel; two opposite side edges of the main board respectively perpendicularly fixed on the two side panels, and a third side edge of the main board perpendicularly fixed on the back panel.

4. The electronic device as claimed in claim 3, wherein the guiding rail includes a guiding portion; the guiding portion being substantially a flanged bar and positioned parallel to the two side panels, two opposite side surfaces of the guiding portion respectively fixed on the main board and the base panel, a third side surface of the guiding portion fixed on one of the two side panels, and a fourth side surface of the guiding portion that is positioned towards the reception portion defining the guiding groove.

5. The electronic device as claimed in claim 4, wherein the guiding rail further includes a retaining portion; the retaining portion being substantially a flange extending from the guiding portion and flatly fixed on the base panel, a side edge of the retaining portion connected to a side edge of the guiding portion.

6. The electronic device as claimed in claim 3, wherein the distribution board includes a case; the case including a main body and an operation member, the main body being substantially a cuboid-shaped box and including an operation side, two sliding sidewalls, and a connection side; the operation side being substantially parallel to the connection side, and the two sliding sidewalls being substantially parallel to each other and perpendicularly mounted between the operation side and the connection side; the sliding rail formed on one of the sliding sidewalls, and the operation member fixed on the operation side.

7. The electronic device as claimed in claim 6, wherein the distribution board further includes a distribution circuit electrically connected to the main board; the distribution circuit received in the main body and including two interfaces partially exposed out from the connection side.

8. The electronic device as claimed in claim 7, further comprising a power supply received in the reception portion and electrically connected to the distribution circuit.

9. The electronic device as claimed in claim 8, wherein the back panel defines an aperture for enabling the power supply to be inserted into and pulled out of the reception portion.

10. The electronic device as claimed in claim 9, wherein the power supply includes two interfaces corresponding to the interfaces of the distribution circuit; and wherein when the power supply is inserted into the reception portion via the aperture, the interfaces of the power supply is capable of engaging with the interfaces of the distribution circuit to electrically connect the power supply with the distribution circuit.
